(19) United States
(12) Patent Application Publication
(10) Pub. No.: US 2009/0189778 A1
(43) Pub. Date: Jul. 30, 2009

(54) METER READING SYSTEM

(76) Inventors: Yin-Tien JUAN, Kaohsiung County (TW); Ying-Yu CHEN, Kaohsiung City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(21) Appl. No.: 12/022,290

(22) Filed: Jan. 30, 2008

(51) Int. Cl. G01R 11/00

(52) U.S. Cl. 340/870.02

(57) ABSTRACT

A meter reading system is provided for use in reading the water, electricity or gas meters, in which a data logger and a meter are installed at user end. When desiring to obtain the readings of a meter at user end, a mobile meter reader sends a control signal via a communication method to the data logger and at the same time obtains the readout of user-end meter connected to the data logger. The meter reading system improves the situation of wrong recording of readout and saves the cost of labor in conventional manual meter reading.

### BACKGROUND OF THE INVENTION

1. Field of the Invention

The present invention relates to a meter reading system, and more particularly to a reading system for water, electricity or gas meters.

2. Related Art

Utilities such as water, electricity and gas are typically connected to the households through pipes and conduits, and meters are installed at households to measure the consumption of water, electricity or gas. Water, electric power or gas companies usually send a work to the households to record readings from the water, electricity or gas meters regularly and bill the consumers.

Manual meter readings at times result in error due to mistakes in manual recording. It is also uneconomical to send a worker to travel far to remote areas for meter reading, given the time and cost of labor incurred.

### SUMMARY OF THE INVENTION

To address the problem just mentioned, the present invention provides a meter reading system employing a mobile meter reader to send control signals via a communication method to control a data logger to obtain the readout of a meter connected thereto.

The present invention discloses a meter reading system comprising a data logger, a mobile meter reader and a plurality of meters. Each meter in the system contains a reader and is electrically connected to a processor chip. The reader stores an identifier of the corresponding meter, and the meter is connected to the data logger via a wired transmission line or wireless transmission protocol. When desiring to obtain the readout of respective meter in the system, the mobile meter reader sends a control signal by microwave transmission or by sending a short message to the processor chip electrically connected to the data logger. The processor chip enables the reader to identify the location of each dial of the meter so as to measure the readout of the meter and transmit the readout and the identifier back to the processor chip. The processor chip sends the readout and identifier of respective meter via the data logger to the mobile meter reader to complete the action of meter reading.

The processor chip can also be embedded in the data logger, where the data logger controls the processor chip and is connected to the meter via a wired transmission line or wireless transmission protocol. As such, the processor chip enables the reader to identify the location of each dial of the meter. After determining the readout of the meter, the reader sends the readout and its identifier to the processor chip in the data logger via a wired transmission line or wireless transmission protocol, which is then transferred to the mobile meter reader to complete the action of meter reading. The meter reading system disclosed in the invention can read simultaneously the readouts of a plurality of meters in the system through the control signals sent by the mobile meter reader. It helps improve the situation of wrong recording of readout and save the cost of labor in conventional manual meter reading.

### BRIEF DESCRIPTION OF THE DRAWINGS

FIG. 1 is a schematic diagram of a meter reading system according to a first embodiment of the invention;

FIG. 2A shows the mechanical structure of the meter in the meter reading system of the invention;

FIG. 2B shows the mechanical structure of the meter in the meter reading system of the invention; and

FIG. 3 is a schematic diagram of a meter reading system according to a second embodiment of the invention.

### DETAILED DESCRIPTION OF THE INVENTION

The implementation of the invention is described in detail below with embodiments in reference to the accompanying drawings.

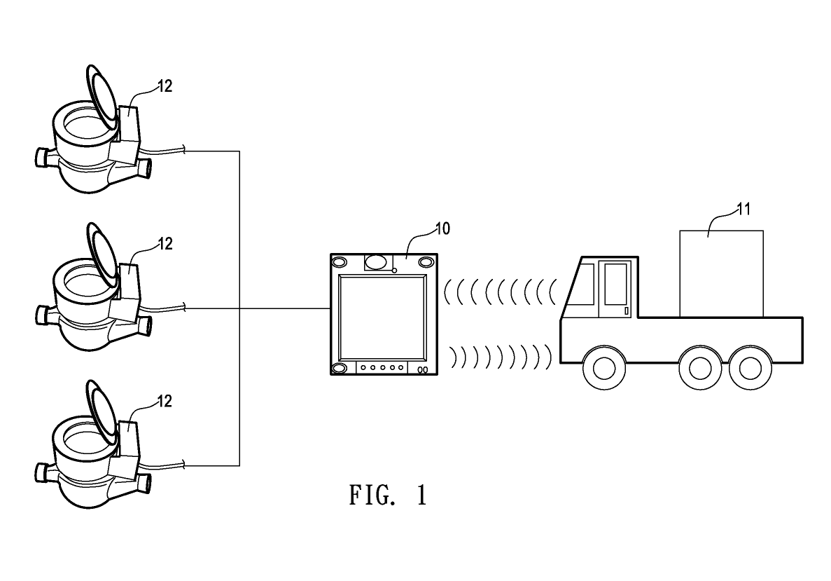

FIG. 1 is a schematic diagram of a meter reading system according to a first embodiment of the invention. As shown, the meter reading system according to the first embodiment of the invention comprises a data logger 10, a mobile meter reader 11 and a plurality of meters 12.

Each meter 12 in the system contains a reader, and the reader stores an identifier corresponding to respective meter 12. Each meter 12 is electrically connected to a processor chip and electrically connected to the data logger 10 via a RS485 transmission line.

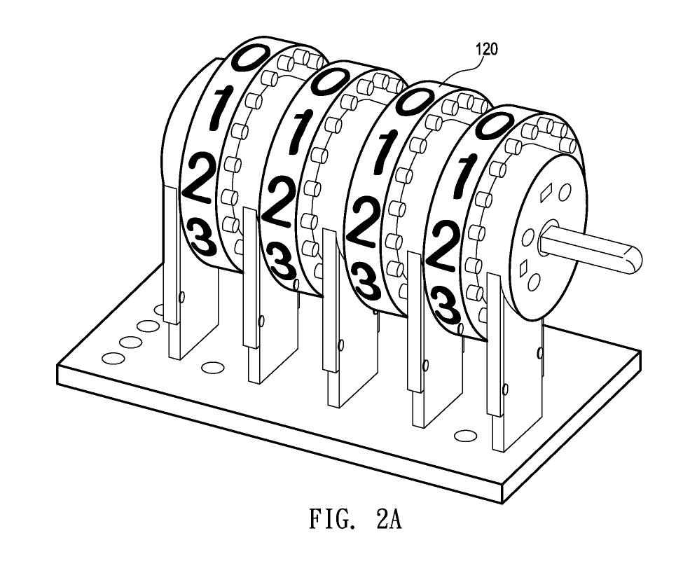

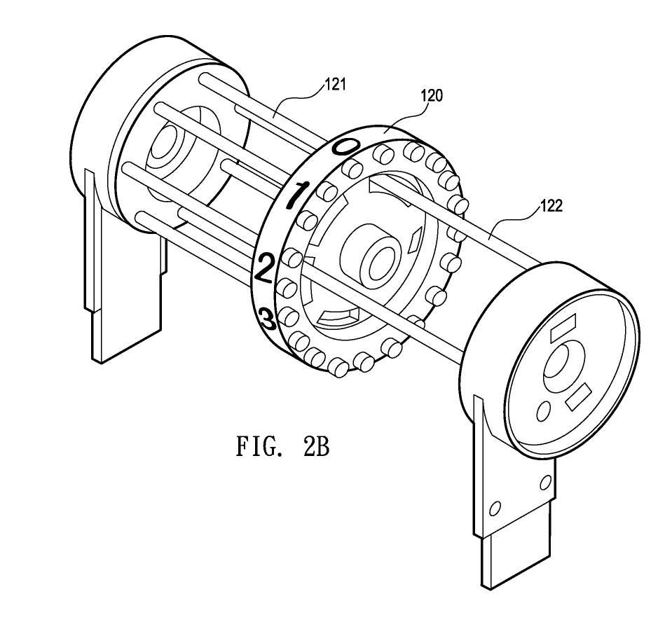

FIG. 2A and FIG. 2B shows the mechanical structure of the meter in the meter reading system of the invention.

As shown in FIG. 1, the mobile meter reader 11 can, according to actual needs, obtain the current readout of respective meter 12 in the system via microwave transmission or short message communication in the steps described below.

When desiring to obtain the readout of individual meter 12 in the system, the user can operate the mobile meter reader 11 to send out a control signal to the data logger 10 through the communication method between the mobile meter reader 11 and the data logger 10. The data logger 10 controls the processor chip to which a meter 12 is electrically connected. The processor chip enables the reader to read the face of dial 120 of respective meter 12 illuminated by the light-emitting tubes 121 disposed on one side of the dial 120. Because the locations of the dial 120 of respective meter 12 are different, each dial has a corresponding code channel, hence resulting in light-blocking and light-transmitting functions. As such, a receiving tube 122 at the other side of the dial 120 of meter 12 receives a set of bright-dark signal, which is further processed and analyzed by the processor chip of respective meter 12 to determine the current location of the dial 120 of meter 12, thereby obtaining the current readout of meter 12.

The readout of respective meter 12 as analyzed by the processor chip of the meter 12 and its identifier are then transmitted back to the data logger 10 via a RS485 transmission line.

After receiving the readout and the identifier of each meter 12 connected to it, the data logger 10 transfers the information to the mobile meter reader 11 via peer-to-peer communication to complete the record action of meter reading.

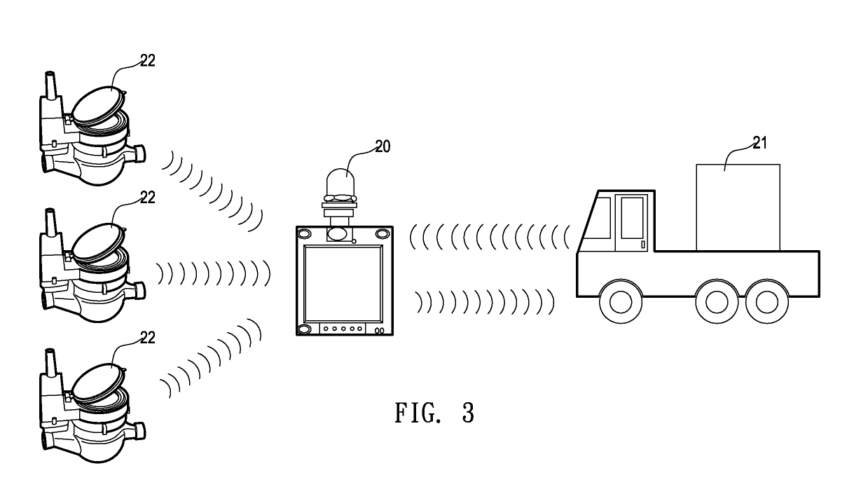

FIG. 3 is a schematic diagram of a meter reading system according to a second embodiment of the invention. As shown, the meter reading system according to a second embodiment of the invention comprises a data logger 20, a mobile meter reader 21 and a plurality of meters 22.

Each meter 22 in the system contains a reader, and the reader stores an identifier corresponding to respective meter 22. Each meter 22 is electrically connected to a processor chip with wireless transmission function and electrically connected to the data logger 20 via a JZ863 wireless transmission protocol.

FIG. 2A and FIG. 2B shows the mechanical structure of the meter in the meter reading system of the invention.

As shown in FIG. 3, each meter 22 is connected to the data logger 20 via JZ863 wireless transmission protocol, while the mobile meter reader 21 can, according to actual needs, obtain the current readout of respective meter 22 in the system via microwave transmission or short message communication in the steps described below.

When desiring to obtain the readout of individual meter 22 in the system, the user can operate the mobile meter reader 21 to send out a control signal to the data logger 20 through the communication method between the mobile meter reader 21 and the data logger 20. The data logger 20 controls the processor chip to which a meter 22 is electrically connected. The processor chip enables the reader to read the face of dial 120 of respective meter 22 illuminated by the light-emitting tubes 121 disposed on one side of the dial 120. Because of the locations of the dial 120 of respective meter 22 are different, each dial has corresponding code channel, hence resulting in light-blocking and light-transmitting functions. As such, a receiving tube 122 at the other side of the dial 120 of meter 22 receives a set of bright-dark signal, which is further processed and analyzed by the processor chip of respective meter 22 to determine the current location of the dial 120 of meter 22, thereby obtaining the current readout of meter 22.

The readout of respective meter 22 as analyzed by the processor chip of the meter 22 and its identifier are then transmitted back to the data logger 20 via JZ863 wireless transmission protocol.

After receiving the readout and the identifier of each meter 22 connected to it, the data logger 20 transfers the information to the mobile meter reader 21 via peer-to-peer communication to complete the record action of meter reading.

The processor chip can also be embedded in the data logger, where the data logger controls the processor chip and is connected to the meter via wired transmission line or wireless transmission protocol. As such, the processor chip enables the reader to identify the location of each dial of the meter. After determining the readout of the meter, the reader sends the readout and its identifier to the processor chip in the data logger via a wired transmission line or wireless transmission protocol, which is then transferred to the mobile meter reader to complete the action of meter reading. The mobile meter reader can be substituted by a stationary meter reader which is installed at a fixed location to obtain the readouts of meters in the system installed in adjacent areas.

To sum up, the meter reading system disclosed by the invention possesses the following advantages:

1. It has extensive applications, applicable to water meter, electric meter and gas meter.

2. The mobile meter reader allows the reading of every meter in the system in a short period of time, thereby saving time and the cost of labor.

3. The meters are read through photoelectric action. As the meter reader is charged and activated only when it is working, it has practical application and consumes less electricity.

4. After the mobile meter reader finishes the reading, each meter's readout in its record system can be relayed to the control center server via WLAN, WiFi, 3G or ADSL for further analysis of the system operation.

The preferred embodiments of the present invention have been disclosed in the examples. However the examples should not be construed as a limitation on the actual applicable scope of the invention, and as such, all modifications and alterations without departing from the spirits of the invention and appended claims shall remain within the protected scope and claims of the invention.

What is claimed is:

1. A meter reading system, comprising:
at least a meter having a reader and a plurality of dials, the reader being electrically connected to a processor chip and storing an identifier of the meter, the processor chip enabling the reader to identify locations of the dials of the meter to determine a readout of the meter, and transfer the readout and the identifier to the processor chip;
a data logger connecting to the processor chip of the meter in a wired or wireless manner to control the processor chip to obtain the readout and the identifier of the reader; and
a mobile meter reader connected to the data logger via a communication method for sending a control signal to the data logger so as to obtain the readout and the identifier of the meter in the data logger.

2. The meter reading system according to claim 1, wherein the dial of the meter contains a light-emitting tube on a first side of the dial and a receiving tube on a second side of the dial, the light-emitting tube illuminating a face of the dial and resulting in light-blocking and light-transmitting functions given the different locations of the dials such that the receiving tube receiving a bright-dark signal and transferring such signal to the processor chip to identify the locations of the dials of the meter so as to measure the readout of the meter.

3. The meter reading system according to claim 1, wherein the mobile meter reader sends the control signal to the data logger via a microwave transmission communication to obtain the readout and the identifier of the meter in the data logger.

4. The meter reading system according to claim 1, wherein the mobile meter reader sends the control signal to the data logger via a short message communication to obtain the readout and the identifier of the meter connected to the data logger.

5. The meter reading system according to claim 1, further comprising transferring the readout and the identifier of the meter obtained by the mobile meter reader to a control center via WLAN, WiFi, 3G or ADSL.

6. The meter reading system according to claim 1, wherein the meter is a water meter.

7. The meter reading system according to claim 1, wherein the meter is an electric meter.

8. The meter reading system according to claim 1, wherein the meter is a gas meter.

9. A meter reading system, comprising:
at least a meter having a reader and a plurality of dials, the reader storing an identifier of the meter, the reader identifying locations of the dials of the meter to measure a readout of the meter;
a data logger having a processor chip and controlling the processor chip in a wired or wireless manner to enable the reader to obtain the readout of the meter and send the readout and the identifier of the meter back to the processor chip; and
a mobile meter reader connected to the data logger via a communication method for sending a control signal to the data logger so as to obtain the readout and the identifier of the meter in the data logger.

10. The meter reading system according to claim 9, wherein the dial of the meter contains a light-emitting tube on a first side of the dial and a receiving tube on a second side of the dial, the light-emitting tube illuminating a face of the dial and resulting in light-blocking and light-transmitting functions given the different locations of the dials such that the receiving tube receiving a bright-dark signal and transferring such signal to the processor chip to identify the locations of the dials of meter so as to measure the readout of the meter.

11. The meter reading system according to claim 9, wherein the mobile meter reader sends the control signal to the data logger via a microwave transmission communication to obtain the readout and the identifier of the meter in the data logger.

12. The meter reading system according to claim 9, wherein the mobile meter reader sends the control signal to the data logger via a short message communication to obtain the readout and the identifier of the meter connected to the data logger.

13. The meter reading system according to claim 9, further comprising transferring the readout and the identifier of the meter obtained by the mobile meter reader to a control center via WLAN, WiFi, 3G or ADSL.

14. The meter reading system according to claim 9, wherein the meter is a water meter.

15. The meter reading system according to claim 9, wherein the meter is an electric meter.

16. The meter reading system according to claim 9, wherein the meter is a gas meter.
